(19) United States
(12) Patent Application Publication
(10) Pub. No.: US 2023/0021529 A1
(43) Pub. Date: Jan. 26, 2023

(54) VIRTUAL ASSISTANT ARCHITECTURE WITH ENHANCED QUERIES AND CONTEXT-SPECIFIC RESULTS FOR SEMICONDUCTOR-MANUFACTURING EQUIPMENT

(71) Applicant: Lavorro, Inc., Palo Alto, CA (US)

(72) Inventors: Arya Priya Bhattacherjee, Livermore, CA (US); David Harrison Webster, Los Altos, CA (US); Scott Michael Braun, San Jose, CA (US)

(21) Appl. No.: 17/868,694

(22) Filed: Jul. 19, 2022

Related U.S. Application Data
(60) Provisional application No. 63/223,905, filed on Jul. 20, 2021.

(51) Int. Cl. H01L 21/67; G06F 40/35; G06F 40/40; G06F 40/295

(52) U.S. Cl. CPC H01L 21/67; G06F 40/35; G06F 40/40; G06F 40/295

(57) ABSTRACT

In one embodiment, a system includes a wafer handling system, processing components, a controller, a virtual assistant, and a natural language processing (NLP) engine. The wafer handling system is configured to hold one or more wafers for processing. The processing components is configured to physically treat the one or more wafers. The controller is configured to operate the processing components. The virtual assistant, in communication with the NLP engine, is configured to receive a user query from a user, understand an intent or context of the user query, and provide a context-specific response to the user query.

### PRIORITY

This application claims the benefit under 35 U.S.C. § 119(e) of U.S. Provisional Patent Application No. 63/223,905, filed 20 Jul. 2021, which is incorporated herein by reference.

### TECHNICAL FIELD

This disclosure generally relates to the manufacturing of semiconductor devices.

### BACKGROUND

Manufacturing of semiconductor devices, such as integrated circuits, is accomplished with specialized semiconductor-manufacturing equipment referred to as semiconductor-manufacturing tools, semiconductor tools, or, in context, tools. The process of manufacturing semiconductor devices involves various steps to physically treat a wafer. For example, material deposition can be accomplished by spin-on deposition, chemical vapor deposition (CVD), and sputter deposition, among other techniques. Tools such as coater-developers and deposition chambers can be used for adding materials to a wafer. Material patterning can be accomplished via photolithography using scanner and stepper tools. Using photolithography, exposure to a pattern of actinic radiation causes a patterned solubility change in a film. Soluble material can then be dissolved and removed. Material etching can be performed using various etching tools. Etching tools can use plasma-based etching, vapor-based etching, or fluid-based etching. Chemical-mechanical polishing tools can mechanically remove materials and planarize a wafer. Furnaces and other heating equipment can be used to anneal, set, or grow materials. Metrology tools are used for measuring accuracy of fabrication at various stages. Probers can test for functionality. Packaging tools can be used to put chips in a form to integrate with an intended device. Other tools include furnaces, CVD chambers, steppers, scanners, physical vapor deposition, atomic layer etcher, and ion implanters, to name a few. There are many tools involved in the process of semiconductor fabrication.

Continuous, accurate, and precise operation of a fleet of semiconductor tools can increase device yield. Such tools, however, tend to require periodic maintenance as well as unscheduled maintenance due to device failure or materials failure. The semiconductor industry often experiences long delays, downtime, and yield loss that cost a significant amount in productivity and depreciation cost of process tools. Semiconductor-manufacturing tools tend to be complex and can be expensive to service and repair both in terms of cost and time. Many device makers have fabs distributed throughout the world. Accordingly, travel latency of expert technicians and engineers can add to the cost of repair and maintenance. Moreover, the maintenance resources and training time for process tools is growing.

Separate from maintenance and repair of semiconductor tools, improving tool usage is also time consuming and costly. Identifying and improving recipes and tool usage parameters for better results is difficult and time consuming. Distributed semiconductor manufacturing environments can increase the challenge of applying best practices on all equipment.

### SUMMARY OF PARTICULAR EMBODIMENTS

In particular embodiments, techniques include a virtual assistant architecture for semiconductor-manufacturing equipment that enhances queries from industry experts producing more meaningful, context-specific multi-media results, to support real-time learning. Techniques include a conversational bot or virtual assistant that identifies human-like natural language queries from field workers when they need to maintain or repair semiconductor-manufacturing tools or improve tool usage and replies to queries with responses that assist with tool usage and repair.

In particular embodiments, the virtual assistant discussed herein uses or integrates natural language processing (NLP) for processing enhanced user queries and providing context-specific results. NLP is, in particular embodiments, a technological process based on deep learning that enables computers to acquire meaning from user text inputs. In doing so, NLP attempts to understand the intent of the input, rather than just the information about the input. There are a number of different ways in which this function is employed. A particular configuration used can be chosen based on desired usage goals. In the context of bots or virtual assistants, integrating NLP gives a virtual assistant more of a human touch or human-like interaction. NLP powered virtual assistants can be configured to assess the intent of input from users and then create responses based on a contextual analysis. NLP-based virtual assistants discussed herein can carry information from one conversation to the next and learn as they go. NLP-based virtual assistants, when trained on large volumes of domain-based data, can in particular embodiments help in identifying and producing domain-specific insights from queries. In particular embodiments, NLP-based virtual assistants can be integrated with user-communication devices such as headsets and wearable visual displays to provide user assistance and automated optimization worldwide and on individual tools.

Advantages of particular embodiments discussed herein include greater semiconductor-manufacturing equipment or tool uptime, lower mean time between failure (MTBF), lower mean time to repair (MTTR), or quicker ramp to yield. Particular embodiments can better predict system or tool creep or better predict process creep. Particular embodiments provide remote tool access as well as remote fab management for process engineers, facilities, maintenance, and field service.

The embodiments disclosed herein are only examples, and the scope of this disclosure is not limited to them. Particular embodiments may include all, some, or none of the components, elements, features, functions, operations, or steps of the embodiments disclosed herein. The subject matter that can be claimed includes not only the particular combinations of features set out in the attached claims, but also includes other combinations of features. Moreover, any of the embodiments or features described or illustrated herein can be claimed in a separate claim or in any combination with any embodiment or feature described or illustrated herein or with any features of the attached claims. Furthermore, although this disclosure describes or illustrates particular embodiments as providing particular advantages, particular embodiments may provide none, some, or all of these advantages.

### BRIEF DESCRIPTION OF THE DRAWINGS

FIG. 1 illustrates an example overview of a semiconductor-manufacturing system providing virtual assistance to a user through a virtual assistant.

FIG. 2 illustrates an example semiconductor-manufacturing system.

FIG. 3 illustrates an example natural language processing (NLP) engine.

FIG. 4 illustrates an example virtual assistant architecture for processing enhanced user queries and providing context-specific results.

FIG. 5 illustrates an example query relation mapping.

FIG. 6 illustrates an example co-referencing in a query.

FIG. 7 illustrates an example architecture for data ingestion, retrieval, and deep learning.

FIG. 8 illustrates an example environment associated with a semiconductor-manufacturing system.

FIG. 9 illustrates an example method for processing a user query and providing a context-specific response to the user query, in accordance with particular embodiments.

FIG. 10 illustrates an example computer system.

### DESCRIPTION OF EXAMPLE EMBODIMENTS

Particular embodiments provide automated assistance on semiconductor-manufacturing equipment (e.g., semiconductor-manufacturing tools) via virtual assistants (also interchangeably herein referred to as smart bots or NLP-based bots). In particular embodiments, techniques include a virtual assistant architecture for semiconductor-manufacturing equipment that enhances queries from industry experts, producing more meaningful, context-specific multi-media results, with real-time learning. In particular embodiments, techniques include a virtual assistant or a smart bot that identifies human-like natural language queries from field workers when they need to maintain or repair semiconductor-manufacturing tools or improve tool usage and replies to queries with one or more responses that assist with tool usage and repair. In particular embodiments, the virtual assistant discussed herein uses or integrates NLP such that the virtual assistant is configured to understand intent of user queries and return responses based on identified user intent, as well as knowledge of tool usage.

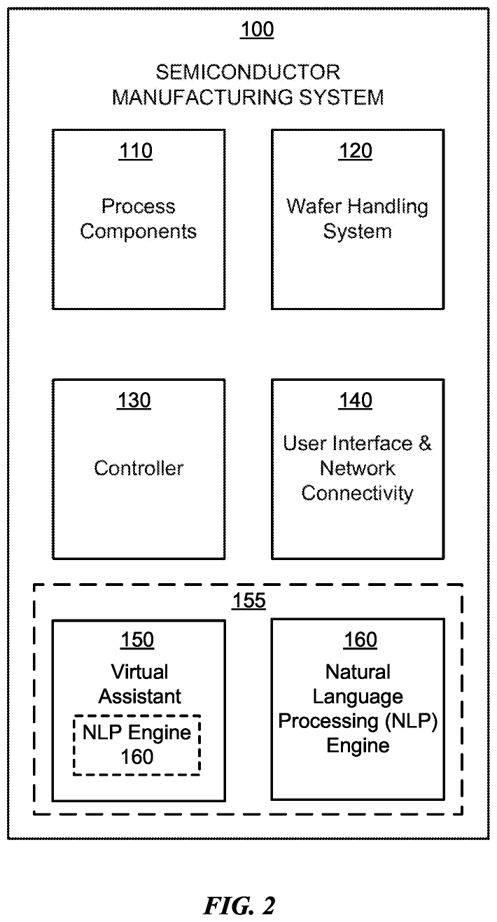

In particular embodiments, a semiconductor-manufacturing system or equipment includes a virtual assistant, among other components, as shown for example in FIG. 2. The virtual assistant can be a smart bot, an NLP-based bot, a text bot, a speech bot, a conversational bot, a chat bot, etc. In particular embodiments, the virtual assistant discussed herein is an NLP-based bot. For instance, the virtual assistant uses or integrates an NLP engine for processing enhanced user queries and providing context-specific results. The NLP engine can parse written or spoken user queries, access stored data (e.g., on-tool or network-based), and provide textual responses. An NLP-based virtual assistant can be used for various tasks and operations, such as to increase tool uptime. An NLP-based virtual assistant includes a virtual assistant or virtual consultant interface that responds to natural language input from a user. NLP-based virtual assistants can parse a natural language query and fetch corresponding data or results. NLP-based virtual assistants can receive spoken input or keyed-in queries. A speech-to-text engine can assist with converting spoken queries to text. Having an NLP-based virtual assistant on a semiconductor-manufacturing system (e.g., semiconductor-manufacturing system 100) enables voice-based trouble shooting, optimization as well as voice control of the tool. Another example embodiment uses an NLP-based bot or virtual assistant on a semiconductor-manufacturing system to improve one or more tool-driven metrics, such as reduce mean time to repair (MTTR) and increase mean time between failure (MTBF).

The virtual assistants can be configured to access and operate system components including advance process control (APC) as well as basic process control. In particular embodiments, virtual assistants can be used to identify causes of yield loss as well as improving yield of one or more semiconductor-manufacturing tools. Virtual assistants and their responses can be metric driven. For example, responses can provide input that increases MTBF, increases equipment or tool uptime, reduces MTTR, reduces queue time variance, and can consider entitlement metrics. The virtual assistant is used for contextual searching of the most logical and relevant information that the user is asking for. An artificial intelligence (AI) or machine learning (ML) engine in the virtual assistants can real time learn from user experience. In particular embodiments, a virtual assistant can be trained to provide assistance for trouble shooting or problem solving. For instance, the virtual assistant can ingest various logs and past actions along with troubleshooting decision-making logic trees to assist a user to access the correct information for the problem solving or lead to remote escalation to a subject matter expert.

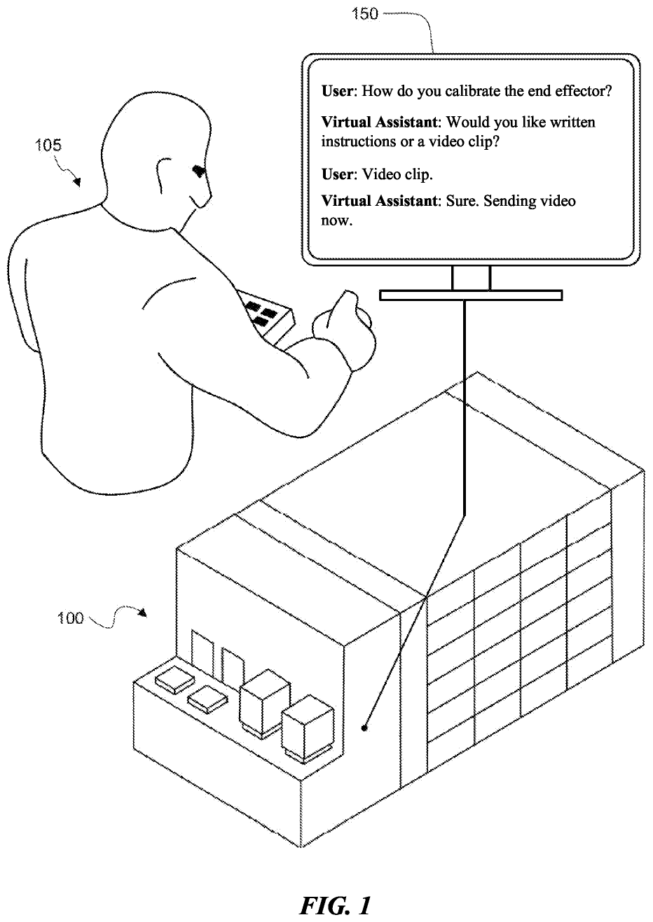

In particular embodiments, the virtual assistant is configured to return or respond to inquiries from users, including at—tool users or remote users. The virtual assistant can also execute actions on the tool such as wafer processing or tool maintenance. By way of a non-limiting example, the virtual assistant can be used for fault detection and classification (FDC). For example, a user working on a given process tool encounters a tool failure or fault condition. Instead of relying on operator training or expert technician availability, the user can enter a text query such as to solve a failure condition. The virtual assistant can respond with solutions, additional questions, information, etc., as shown for example in FIG. 1. The solutions and additional help can be in the form of text, audio, video, augmented reality (AR), and automated actions. For example, a given process tool has a failure. By way of text inquiry, a user asks for solutions to address the tool failure. Input can be an error code entered by the user, or the virtual assistant can electronically access error codes and diagnostic data. The virtual assistant can return answers in text, such as steps to take to fix the tool, or display documents and images to assist or explain a particular repair procedure. Alternatively, the virtual assistant can access video showing steps to fix the tool. If, for example, a focus ring is identified as part of a tool failure, the virtual assistant or semiconductor-manufacturing system can return a video showing the best-known way to replace the focus ring. If, instead of tool failure, the issue relates to poor processing, such as non-uniform etching, then an inquiry about how to improve etch uniformity for a given gas, temperature, or film to etch can be entered via the virtual assistant, and then the virtual assistant can return a best-known recipe for a given etch. This best-known recipe can be obtained from data used at any other tool in network or from an extended network, such as from outside a corresponding organization.

In particular embodiments, users can connect to virtual assistants using headsets and heads-up displays. In particular embodiments, semiconductor-manufacturing systems have AR user hardware. Both tool use and tool maintenance/repair can be captured and delivered to users via video in AR or virtual-reality (VR) systems. For example, with AR equipment, a user (e.g., a field service engineer) can observe a part of a semiconductor-manufacturing system to repair or service, and information is directly overlaid on that particular semiconductor-manufacturing system. This can reduce training time of tool technicians. Instead of having extensive classes to cover all service procedures, detailed instructions can be delivered to a technician at a tool on demand. Images and video can be overlaid on device parts. Audio instructions can accompany video. The connected virtual assistant can respond to natural language requests such as “How do I access the resist pump on this track tool?” The AR system can guide a user to an access panel, indicate fasteners to remove, display a location of the pump, and instruct on how to repair/replace. Any suitable questions can be answered with tutorials, and any type of image format can be overlaid on tools such as an arrow or a visually highlighted part. This provides an assistant-immersed experience.

An example embodiment includes a head gear system in communication with a virtual assistant on a semiconductor-manufacturing system (e.g., semiconductor-manufacturing system 100). The head gear system includes wearable inputs and outputs to interface with a given tool. Such a head gear system can include a speaker, a microphone, and can also include a visual display. The head gear system can receive natural language input. The headgear system or a processor in communication with a head gear unit can translate spoken language into text to interact with the virtual assistant on the semiconductor-manufacturing system.

One embodiment includes use of on-tool AI for semiconductor equipment. One or more AI engines can be incorporated in a semiconductor-manufacturing system (e.g., semiconductor-manufacturing system 100). Alternatively, the AI engine can be in a network communication with the semiconductor-manufacturing system. Such an AI engine can assist users (e.g., local users or remote users) with many operations such as to correct failures, optimize operation, and repair failures. The AI engine can access any or all of these models and systems in responding to user queries, commands, and actions. In some embodiments, the AI engine can monitor tool usage, recipe selection, operating parameters, and other actions, and then suggest to user optimized recipes, warn or predict potential failures, recommend repairs to increase uptime, and other actions and suggestions to generally increase uptime and yield. Deep learning via an AI engine or other analysis tools can be used on a semiconductor-manufacturing system to enhance function of onboard operational capabilities of the semiconductor-manufacturing system. Response and actions of the AI engine can be in response to user queries or background monitoring of tool usage. The AI engine can include a web interface configured to compare and contrast data sets from different pieces of semiconductor equipment. The AI engine on a tool can provide a comparison between best known methods and apply deep learning to establish which method, of a set of possible methods, performs better. This comparison can be based on AI analysis.

Particular embodiments herein can augment systems and methods providing automated assistance on semiconductor equipment via virtual attendants and virtual consultants (bots or virtual assistants), such as those disclosed in U.S. patent application Ser. No. 17/353,362, entitled Automated Assistance in a Semiconductor Manufacturing Environment, which is herein incorporated by reference in its entirety and discloses, among other things, using software bots, artificial intelligence (AI), machine learning (ML), and NLP on semiconductor manufacturing tools. In particular embodiments, techniques include virtual assistants, AI engines, ML programs, and language-processing (LP) engines integrated with user-communication devices (such as headsets or wearable visual displays) to provide user assistance and automated optimization worldwide and on individual tools. In particular embodiments, on-tool automated assistants (e.g., virtual assistants, AI engines) can function as a first point of information and resource before escalating to field service engineering.

FIG. 1 illustrates an example overview of a semiconductor-manufacturing system 100 providing virtual assistance to a user 105 through a virtual assistant 150. The system 100 can be any apparatus configured to process/treat semiconductor wafers or other micro-fabricated substrates. For example, semiconductor-manufacturing system 100 can be a coater-developer, scanner, etcher, furnace, plating tool, metrology tool, etc. User 105 can be any operator such as a process engineer, technician, field service engineer, among others. Semiconductor-manufacturing system 100 includes an on-board virtual consultant, such as the virtual assistant 150. The virtual assistant 150 can be embodied as any of, or any combination of, smart bot, NLP-based bot, text chat bot, speech-to-text chat bot, or AI engine, with LP or NLP. With such a system, a given user can directly query the virtual assistant 150 to receive answers to any questions such as how to perform a given wafer treatment process, what errors were recorded in a given time frame, how a particular component is repaired or replaced, and so forth.

FIG. 2 illustrates an example semiconductor-manufacturing system 100. Although a particular semiconductor-manufacturing system is described and illustrated, this disclosure contemplates any suitable semiconductor-manufacturing system. In the example of FIG. 2, semiconductor-manufacturing system 100 includes process components 110, a wafer handling system 120, a controller 130, user interface and network connectivity components 140. The semiconductor-manufacturing system 100 further includes one or more software modules. The software modules can include software module directed to control one or more of the hardware components. The software modules can further include one or more software modules provided by a separate entity and directed to improve the usability of the semiconductor manufacturing system 100. As indicated by the box 155, software module of this type can include a virtual assistant 150 and an NLP engine 160. In some embodiments, the NLP engine 160 can be included as a separate entity or component in the semiconductor-manufacturing system 100. In other embodiments, the NLP engine 160 can be integrated into or be part of the virtual assistant 150 (e.g., as shown by dotted line or box).

The process components 110 are configured to physically treat one or more surfaces of wafers. The particular process components 110 depend on a type of tool and treatment to be performed. Particular embodiments function on any number or type of process tool. For example, with an etcher tool, process components 110 can include a processing chamber with an opening to receive a wafer. The processing chamber can be adapted for vacuum pressures. A connected vacuum apparatus can create a desired pressure within the chamber. A gas-delivery system can deliver process gas or process gases to the chamber. An energizing mechanism can energize the gas to create plasma. A radio frequency source or other power delivery system can be configured to deliver a bias to the chamber to accelerate ions directionally. Likewise, for a coater-developer tool, such process components 110 can include a chuck to hold a wafer and rotate the wafer, a liquid dispense nozzle positioned to dispense liquid (e.g., a photoresist, developer, or other film-forming or cleaning fluid). As can be appreciated, the coater-developer tool can include any other conventional componentry.

The wafer handling system 120 is configured to hold one or more wafers (substrates) for processing. Wafers can include conventional circular silicon wafers, but also includes other substrates. Other substrates can include flat panels such as for displays and solar panels. The wafer handling system 120 can include, but is not limited to, wafer receiving ports, robotic wafer arms and transport systems, as well as substrate holders including edge holders, susceptors, electrostatic chucks, etc. In some embodiments, the wafer handling system 120 can be as simple as a plate to hold a wafer while processing. The wafer handling system 120 can include handlers and associated robotics to receive wafers from a user or wafer cartridge, transport to processing modules, and return to an input/output port or other module within the tool.

The controller 130 is configured to operate the process components 110. The controller 130 can be positioned on the tool (e.g., semiconductor-manufacturing tool) or can be located remotely connected to the tool. The controller 130 can include all of the tool processor, memory, and associated electronics to control the tool including control of robotics, valves, spin cups, exposure columns, and any other tool component.

The user interface and network connectivity components 140 can include any display screen, physical controls, remote network interfaces, local interfaces, and so forth.

The virtual assistant 150 is configured to understand intent of user queries and return responses based on identified user intent, as well as knowledge of tool usage. The virtual assistant 150 uses an NLP engine 160 or works in communication with the NLP engine 160 for processing enhanced user queries and providing context-specific results. For instance, the virtual assistant 150, using the NLP engine 160, can identify human-like natural language queries from field workers when they need to maintain or repair semiconductor-manufacturing tools or improve tool usage and replies to queries with one or more responses that assist with tool usage and repair. As depicted, the virtual assistant 150 can include or integrate the NLP engine 160 (e.g., as shown by dotted lines). Alternatively, the NLP engine 160 can be installed on or within the semiconductor-manufacturing system 100 as a separate entity. The virtual assistant 150 can be installed on or within the semiconductor-manufacturing system 100 for immediate use without any network connection. In addition or as an alternative, virtual assistant 150 can be installed in an adjacent server or network. Virtual assistant 150 can be installed at a remote location and can connect or otherwise support any number of different tools.

The virtual assistant 150 can have various alternative architectures. For example, the virtual assistant 150 can have a corresponding processor and memory positioned at the tool (e.g., within the tool, mounted on the tool, or otherwise attached to the tool). Alternatively, the virtual assistant execution hardware can be located remotely, such as in a server bank adjacent to a tool (or fab), or the virtual assistant can be executed while geographically distant (e.g., in a separate country). Configurations can have redundant, multiple, or complementary virtual assistants. For example, particular embodiments can include an on-tool virtual assistant as well as a remote virtual assistant with either virtual assistant able to respond to inquiries and execute actions. Alternatively, an on-tool virtual assistant can address one group or type of inquiry (e.g., diagnostic information), while a remote server-based virtual assistant can access deep learning and network data, as well as data from other tools within an integration flow to predict failures and suggest actions for optimization.

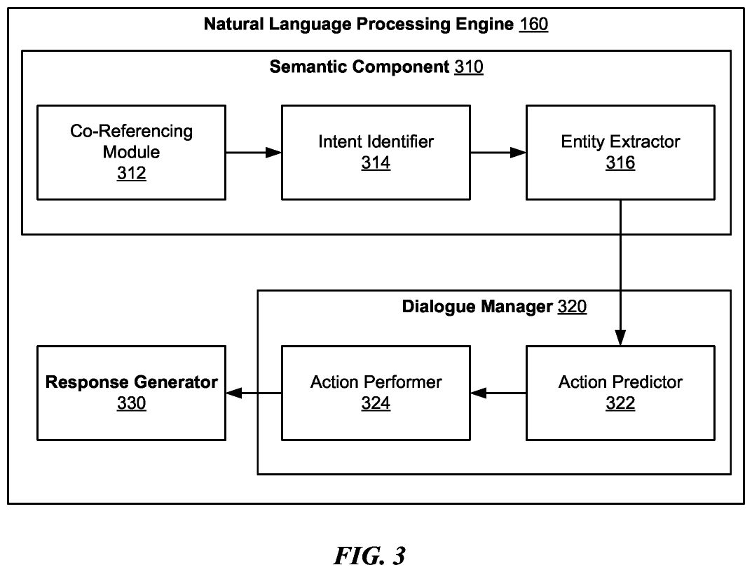

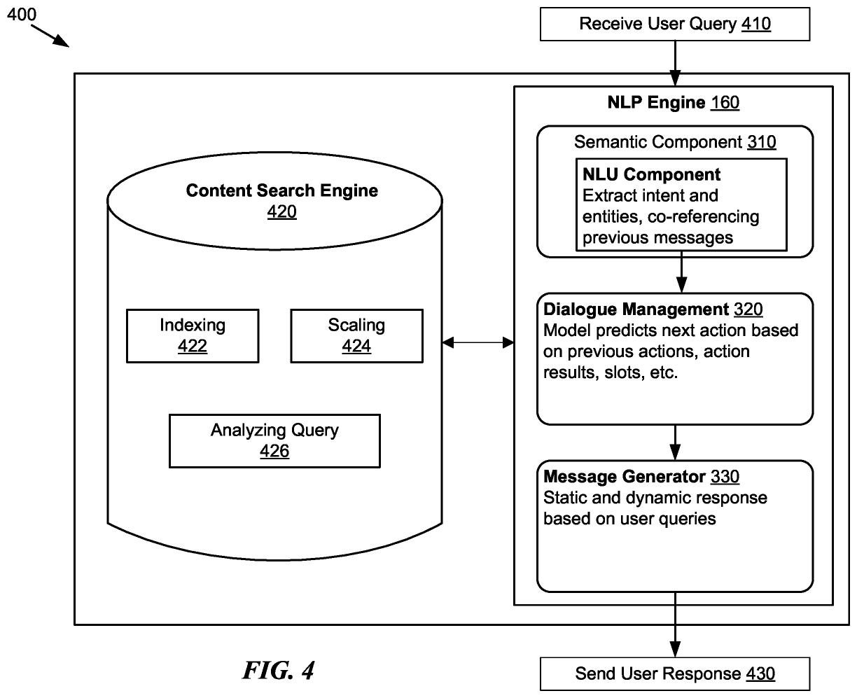

The NLP engine 160 is configured to identify intent and entities from a user query (e.g., written or spoken user query), predict an action based on the identified intent and entities, and generate a response based on the user query and predicted action. In particular embodiments, the NLP engine 160, works in communication with the virtual assistant 150, to receive the user query and generates the response. The NLP engine 160 discussed herein can be trained, as an example, based on a transformer model architecture. Particular embodiments herein include using relatively large volumes of semiconductor data to train the NLP engine 160. The trained NLP engine 160 can be used for various tasks including, for example and without limitation, named entity recognition, text generation, question answering, etc. The transformer model in the NLP engine 160 is an architecture that aims to solve sequence-to-sequence tasks while handling long-range dependencies with relative ease. In contrast to directional models, which read the text input sequentially (left-to-right or right-to-left), in particular embodiments, a transformer encoder reads or analyzes an entire sequence of words at once or together. This method can be considered bidirectional, though it can be more accurate to say that this processing is non-directional. This characteristic helps the NLP engine 160 to learn the context of a word in a user query based on its surroundings (e.g., words, phrases, and information positioned both left and right of the word). The NLP engine 160 is discussed in further detail below in reference to at least FIGS. 3 and 4.

Particular embodiments herein use the virtual assistant 150 configured with the NLP engine 160 to find linguistic expressions in a given text (e.g., user query) that refer to any semiconductor-related entity and to resolve linguistic expressions by replacing pronouns with noun phrases. The NLP engine 160 can substantially understand the meaning of each word based on context both to the right and to the left of the word, which enables the virtual assistant 150 in particular embodiments to learn context. In particular embodiments, techniques include using virtual assistants to extract, process, cleanse, parse, and store semiconductor-related multimedia data (including but not limited to text, images, videos and tables) in a structured format that facilitates gaining insights of data. In particular embodiments, virtual assistants store the parsed information into a search engine (e.g., content search engine 420) that is scalable and resilient and is designed to allow relatively fast, full-text searches.

As an example, particular embodiments use an NLP-based virtual assistant 150 that is trained on large volumes of semiconductor data, identifies best results, and then sorts results based on a score after getting a response from a corresponding search engine. Particular embodiments include using an NLP-based virtual assistant 150 that identifies intent and entities from user queries using NLP (e.g., NLP engine 160) and predicts a next action based on a confidence score with respect to intent identified using a dialogue manager (e.g., dialogue manager 320). In particular embodiments, a virtual assistant controller can, based on a predicted action, perform a requested task and return a response to the user.

FIG. 3 illustrates an example NLP engine 160. As illustrated, the NLP engine 160 includes components including a semantic component 310, a dialogue manager 320 and a response generator 330, each of which can include sub-components. For instance, the semantic component 310 (also interchangeably referred to herein as a natural language understanding (NLU) component) can include a co-referencing module 312, an intent identifier 314, and an entity extractor 316. The dialogue manager 320 can include an action performer 320 and an action predictor 324. These components 310, 312, 314, 316, 320, 322, 324, and 330 are communicatively coupled to each other and can cooperate with each other to perform the intended operations of the NLP engine 160 discussed herein. Each of these components is discussed in detail herein.

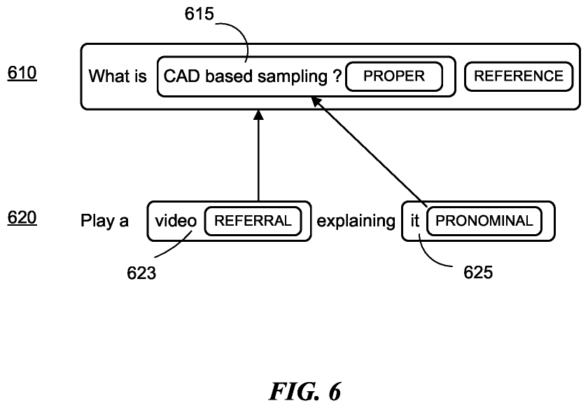

In particular embodiments, the semantic component 310, at a high level, is configured to understand or infer an overall context (e.g., semantics) of a user query. Specifically, the semantic component 310 is configured to receive a user query via a virtual assistant 150, co-reference any previous data or information (e.g., past interactions between user and virtual assistant, previous messages) related to the query, identify user intent from the query, and extract one or more entities. The semantic component 310 performs its operations using sub-components 312, 314, and 316. For instance, the co-referencing module 312 receives a given user query and identifies any co-references from previous user's conversations. Stated differently, the co-referencing module 312 determines whether information from previous or past conversation of the user and the virtual assistant should be accessed. FIG. 6 illustrates an example co-referencing in a query.

The intent identifier 314 is configured to identify an intent of a user in a given user query. In particular embodiments, intent identification is a core function of the NLP engine 160. Understanding what a user wants to convey or accomplish is an important aspect to answering the user's queries. In particular embodiments, this is performed by the intent identifier 314. In particular embodiments, the intent identifier 314 classifies a user's message into different intents. Examples of different intents can be generated. These generated intents can then be used to fine tune Bidirectional Encoder Representations from Transformers (BERT) for the task of multi-class classification with respect to semantic sense of the text. The following are some non-limiting examples of various intents that can be used in particular embodiments:
a. Query 1 LEARN— Message is a query (image/video/manual), such as, e.g., “What is the purpose of vacuum calibration?”
b. Graph 1 ANALYZE— Message is a graph-related query, such as, e.g., “Show me the variance of xyz.”
c. Alarm 1 ANALYZE— Message is a alarm-related query, such as, e.g., “Show me the alarm data for xyz tool.”
d. Hierarchy 1 ANALYZE— Message is get hierarchy of dynamic data, such as, e.g., “Show me the hierarchy of dynamic data.”
e. Affirm—Message is an affirmation, such as, e.g., “Agreed.”
f. Deny—Message is a denial, such as, e.g., “I need something else.”
g. Get Type 1 (Get image, Get video, Get pdf)—Message is specifying a type of response needed, such as, e.g., “I need image answers.”
h. Greet—Message is a greeting, such as, e.g., “Hello, there!”
i. Goodbye—Message is a farewell message, such as, e.g., “Bye.”
j. Virtual assistant Challenge—Message is a virtual assistant challenge, such as, e.g., “Are you a bot?”

In particular embodiments, the entity extractor 316 (also interchangeably referred to herein as an entity recognizer) enables identification/extraction of entities in the query to understand the user query more precisely. The entity extractor 316 further supports parsing of the response. Particular embodiments use different types of entity extractors or recognizers based on the type of query. In particular embodiment, for graph-related queries, an entity can be a chamber name or an attribute name or containing both. In particular embodiments, for alarm-related queries, an entity can be a datetime string in the message, severity mentioned (either high or low), or tool name. The particular entities can be based, for example, on particular requirements or idiosyncrasies of individual operators, user, groups of users, departments, fabs, tools, companies, etc.

In particular embodiments, the dialogue manager 320, at a high level, is configured to predict a next action that the virtual assistant 150 should perform based on results produced by the semantic component 310. Specifically, the dialogue manager 320 is configured to receive any co-referencing data or information (e.g., previous messages, actions), identified intent, and extracted entities associated with the given user query from the semantic component 310, and predicts a next action or sequence of steps the virtual assistant 150 should perform in response to the query. The dialogue manager 320 performs its operations using sub-components 322 and 324. For instance, an action predictor 322 identifies a relevant action the virtual assistant 150 should perform based on the intent identified. An action performer performs a next sequence of steps based on the entities identified by the entity extractor 316. In particular, the action performer 324 can call identified-intent handlers or action handlers to get relevant information required by a user and provide the relevant information to the response generator 330 to generate a message (e.g., user response, reply to a given user query) accordingly. In particular embodiments, following are some non-limiting examples of various action handlers:
a. Static Data Handler
   This determines whether a message received is a query. If the message is a query, then the response is fetched from an elastic search. Particular embodiments use project-wise indices of primarily textual content such as Portable Document Format (PDF) files, images, and videos. These can also include configurations, program documents, configuration and calibration results as well as tables of tool control variables. When a query is received, all the three indices are searched and parsed in a structure that, in case of a PDF-related query, contains page number, manual name, main heading, subheading, and paragraph and, in case of a visual-content query (e.g. video, image, etc.), contains file name, description, and associated text.
b. Static Query Handler
   This determines whether the message received is a generalized message, such as, e.g., a greet message, a virtual assistant-challenge message, or a farewell message. If the message is a generalized message, then a response is generated based on the type of generalized message. The following are examples:
      Greet—“Hey, how may I help you?”
      Goodbye—“It was nice talking to you. Hope to see you soon!”
      Virtual assistant challenge— “I am a bot, powered by XYZ Company!”
f. Graph Data Handler
   This determines whether the message received is a graph-related query. If the message is a graph-related query, then the entities are extracted from the message. For example, an entity can be a chamber name or an attribute name or contain both. Based on the entities extracted, the relevant graph data is fetched from MongoDB and shown to the user.
g. Alarm Data Handler
   This determines whether the message received is an alarm-related query. If the message is an alarm-related query, then the entities are extracted from the message. For example, an entity can be a datetime string in the message, severity mentioned (either high or low), or tool name. Based on the entities extracted, the data from the alarm.csv file is parsed and shown to the user.

The response generator 330 is configured to generate an appropriate response for a given query to be provided to the user through the virtual assistant 150. In particular embodiments, the response generator 330 works in close communication and/or cooperation with the action performer 324, including one or more action or intent handlers discussed above, to generate a response or message. As an example, for generating a response for a graph-related query, the response generator 330 receives relevant graph data from a graph data handler discussed above, generates a message to include the relevant graph data, and sends the generated message to the virtual assistant 150 to display it to the user. As another example, for generating a response for a alarm-related query, the response generator 330 receives data from a parsed alarm.csv file from the alarm data handler discussed above, generates a message to include the data from the parsed alarm.csv file, and sends the generated message to the virtual assistant 150 to display it to the user.

FIG. 4 illustrates an example virtual assistant architecture 400 for processing enhanced user queries and providing context-specific results. As discussed elsewhere herein, the virtual assistant 150 works in communication with or uses the NLP engine 160 to process user queries and provide context-specific results. For instance, the virtual assistant 150 receives a user query 410. The user query 410 can be, for example and without limitation, a data query, a graph-related query, an alarm-related query, etc. By way of an example, the user query 410 can be “How do you calibrate the end effector?”, as shown in FIG. 1. The virtual assistant 150 sends the user query 410 to the NLP engine 160 for processing. In particular embodiments, data accessible to the virtual assistant 150 herein can be extracted (e.g., text data parsed) from, for example, user manuals, PDFs files, PowerPoint (PPT) files, or other text-data files, along with the metadata of media files stored in a corresponding search engine, such as a content search engine 420. In particular embodiments, the NLP engine 160 works in communication with the content search engine 420 to generate an appropriate response for the user query 410. For instance, in response to the user query 410, the search engine 420 can search for query responses while a semantic component 310 sorts potential responses based on a score generated to identify a response deemed to have a highest match with the user query 410.

Upon receiving the user query 410, the semantic component 310 (or the NLU component) of the NLP engine 160 identifies user intent and extracts one or more entities in the user query 410, and also determines whether there any co-referencing previous messages. The NLU component sends its results to the dialogue manager 320 for dialogue management, which involves predicting a next action to be performed by the virtual assistant 150 based on the identified intent, extracted entities, and co-referencing previous messages. In particular embodiments, the next action and associated action item(s) (e.g., requested data or information by the user) can be determined by an action handler, such as static data handler, static query handler, graph data handler, alarm data handler, etc. In some embodiments, the dialogue manager 320 can retrieve any relevant data, as requested in the user query 410, from the content search engine 420. Once retrieved, the dialogue manager 320 can sort, filter, or score the data retrieved from the content search engine 420 to generate filtered data to be included in a response to the user. By way of an example and without limitation, if there are 10 items (e.g., answers to user query 410) retrieved from or provided by the content search engine 420, the dialogue manager 420 can score each of these 10 items and identify an item with the highest score to be included in the user response. Additionally, the ranking of the results can be augmented by the intent-classification used in the dialogue manager 320 to prioritize how the user sees results. In some embodiments, the item with the highest score also has a highest match with the user query 410.

The content search engine 420 stores extracted text data from user manuals, PPTs, metadata of media files, tool configuration files, recipe or process direction data-sets, calibration files or any other files associated with semiconductor-manufacturing tools. Data stored in the content search engine 420 can be used to fulfill user queries, including the user query 410. As illustrated, the content search engine 420 can perform one or more operations in relation to the user query 410. For instance, an indexing operation 422 can be performed to index the extracted text data in a data store, look up any requested data, and retrieve/provide the requested data. Scaling operation 424 can be performed to scale the retrieved data in an appropriate format. Analyzing query operation 426 can be performed to analyze the user query 410 or any other query from the NLP engine 160 and perform subsequent operations thereon.

Once the dialogue manager 320 determines the next action and any action items (e.g., data retrieved from the content search engine 420), the response or message generator 330 can generate an appropriate response 430 to the user query 410. In particular embodiments, the message generator 330 is configured to generate static responses (e.g., results based on pre-defined and curated content such as installation or user operation guides) and/or dynamic responses (e.g., quantitative and qualitative data based on the runtime environment and recent behavior of the semiconductor manufacturing tool such as chamber pressure for the past ten wafer runs) based on user queries. Upon generating the appropriate response 430, the message generator 330 sends the response to the virtual assistant 150 for provisioning to the user.

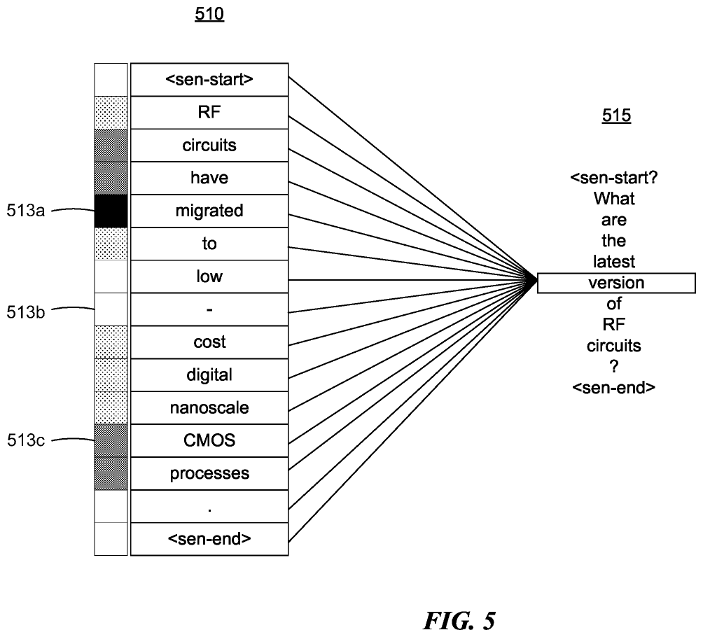

FIG. 5 illustrates an example query relation mapping in which an NLP engine is trained on semiconductor data and matches components in the query with components in trained data to identify relative context. In addition, FIG. 5 illustrates an example mapping between elements of a previous query 510 and elements of a current query 515. In the example of FIG. 5, a user and a virtual assistant 150 have engaged in an ongoing series of queries. Using the techniques described herein, the virtual assistant 150 stores those queries over time for both the individual user and other users within the same environment or context in order to improve the virtual assistant's 150 ability to respond to future queries.

Upon receiving a new query 515, the virtual assistant 150 (or a sub-module thereof) parses the query 515 to better understand the request in the context of the communication sequence. In the illustrated example, the virtual assistant 150 can analyze the query “What are the latest version of RF circuits?” in an attempt to better understand the user's request and provide a more informative or relevant response. The virtual assistant 150 (e.g., through the NLP engine) analyzes the query 515 in the context of previous queries, such as past query 510. In particular, the virtual assistant can perform query relation mapping to associate particular elements of the past query 510 to the new query 515. Although FIG. 5 illustrates this mapping as being performed on each element within the past query 510, the virtual assistant 150 can eliminate certain terms based on linguistic or semantic criteria. As an example, the virtual assistant 150 can eliminate known stopwords or irrelevant punctuation. As another example, the virtual assistant 150 can attempt to match the type of speech of a subject term in the new query 515 to the type of speech of terms in the previous query 510. In the example shown in FIG. 5, the virtual assistant has assessed the relative likelihood of relevance of the terms of the previous query 510 to the subject term in the new query 515, which in this example is “version.” The weights are represented, for illustrative purposes only, by the color-coded weight levels 513a-513c. Darker shaded squares correlate to the relative weight. Therefore, the likelihood of relevance indicated by the square 513b, corresponding to “-” is lower than the likelihood of relevance indicated by the square 513c, corresponding to “CMOS,” which is in turn lower than the likelihood of relevance indicated by the square 513a, corresponding to “migrated.” The relative weights assigned to each term can be used to determine the most relevant terms from the past query 510 to the new query 515 as well as to weight how the terms are used in assessing the meaning of the new query 515, among other uses.

FIG. 6 illustrates example co-referencing in a query, in which a co-referencing module (e.g., co-referencing module 312) determines whether information from previous or past conversations of the user and the virtual assistant should be accessed. FIG. 6 illustrates a mapping between a previous query 610 and a current query 620. For the sake of brevity, not illustrated is the response form the virtual assistant 150 to the first query 610 or the response determined after analyzing the second query 620. Using the techniques described herein, the virtual assistant 150 analyzes queries in a conversation, or otherwise defined sequence of queries, over time in order to improve the virtual assistant's 150 ability to respond to future queries.

FIG. 6 illustrates a first query 610— “What is CAD based sampling?”— followed by a second query 620— “Play a video explaining it.” One of the challenges of the virtual assistant 150 is identifying the meaning of “it”—term 625. Analyzing term 625 within the context of only query 620, one could determine that term 625 refers to “video”—term 623. However, in that case, the request within the query—“Play a video explaining the video.”— is self-referential and nonsensical. Therefore, to provide a response that better aligns with the intent of the user, the co-referencing module of the virtual assistant 150 reviews the first query 610 for potential referents for term 625. In reviewing query 610, the virtual assistant 150 has determined that “CAD based sampling”—term 615—is the most likely intended referent. This can be determined, for example, by evaluating a confidence score or other similar weighting mechanism for previous queries. Through this analysis, the virtual assistant 150 can determine that the request in query 620 is in fact a continuation of the request in query 610 and should be interpreted as “Play a video explaining CAD based sampling.” As illustrated in FIG. 6, terms within the respective queries are labeled by a semantic component for better understanding or identification of the co-referencing.

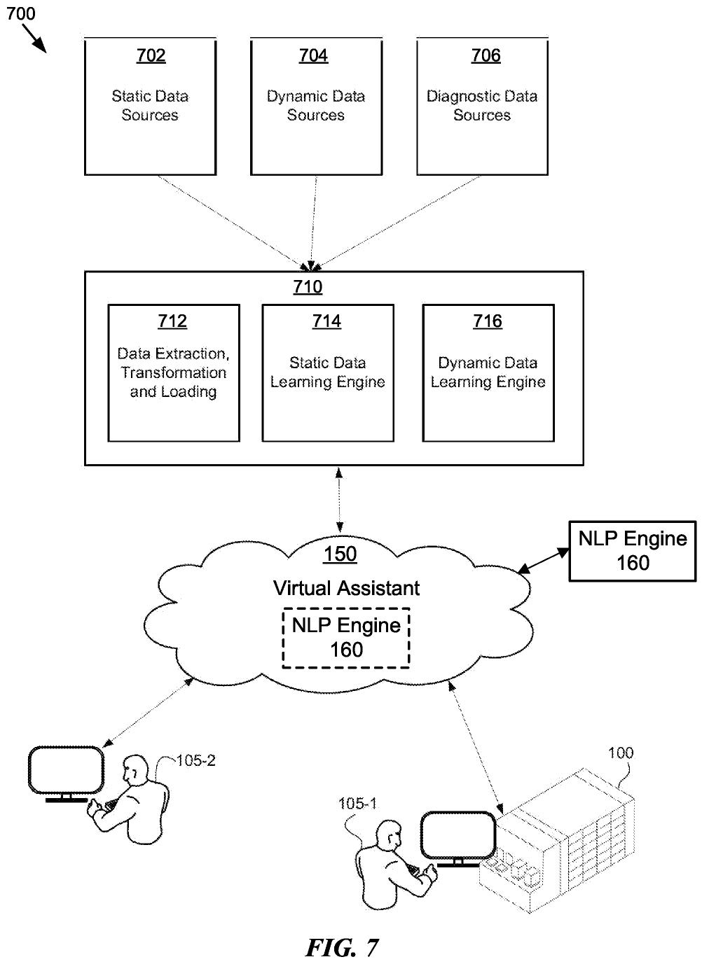

FIG. 7 illustrates an example architecture 700 for data ingestion, retrieval, and deep learning. Data sources 702, 704, and 706 can be accessed to extract data (e.g., from user manuals, PDFs files, PPT files, or other text-data files, along with the metadata of media files). This data can be formatted or raw. Data processor 710 can include a data extraction, transformation, and loading (ETL) module 712, a static data learning engine 714 for learning from static data, a dynamic data learning engine 716 for learning from dynamic data, as well as any other data learning and formatting engines such as NLP engines. Processed data can be made available to or pushed to a virtual assistant 150 and/or the NLP engine 160. The virtual assistant 150 and/or the NLP engine 160 can use the processed data to fulfill a user query. The virtual assistant 150 can include the NLP engine 160 or the NLP engine 160 can be a separate entity, as discussed elsewhere herein. Virtual assistant 150 can be located on a given network or located within a semiconductor-manufacturing system 100. Local user 105-1 can directly access, for example, the virtual assistant 150 at the semiconductor-manufacturing system 100. Remote user 105-2 can also access semiconductor-manufacturing system 100 via a network connection.

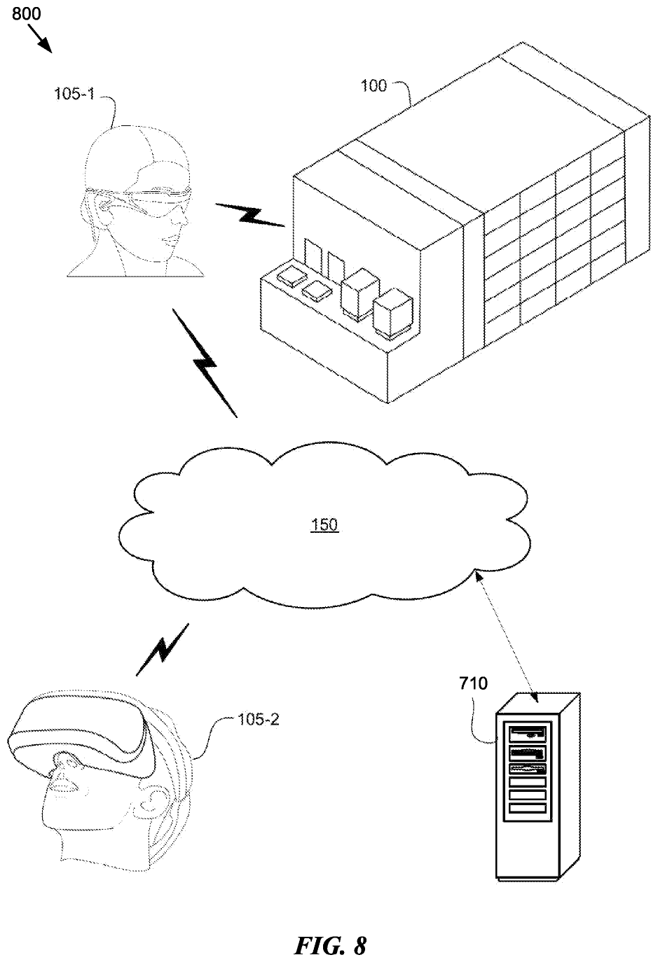

FIG. 8 illustrates an example environment 800 associated with a semiconductor-manufacturing system 100. In the example environment 800, a local user 105-1 can physically access the semiconductor-manufacturing system 100. This can be accomplished via any user input. In this example, the local user 105-1 is equipped with an AR headset. This can include visual overlay of parts and components when viewing the tool or control panel. Through the AR headset, the local user 105-1 can communicate with a virtual assistant 150 such as by natural language speech. The virtual assistant 150 can return answers via audio, text, video, or other media. The virtual assistant 150 can be on-tool or network located and can access data processor 710 to retrieve stored and real-time data. A remote user 105-2 can be in communication with both the virtual assistant 150 and the local user 105-1. With a VR headset, the remote user 105-2 can view video and audio from the local user 105-1, send instructions to the local user 105-1. Both users can be collaborative, or expert and novice. For example, the expert user can be remotely located and assist the local user located at a location that can be in a different country or area. Alternatively, the local user can be an expert on training various remote users on tool operation and maintenance. Although a particular interaction between users and a particular virtual assistant is described and illustrated, this disclosure contemplates any suitable interaction between a user and any suitable virtual assistant. Also, this disclosure contemplates any suitable number of users and any suitable number of virtual assistant configurations to provide automated assistance for semiconductor manufacturing systems. In particular embodiments, assistance can be provided without training or travel.

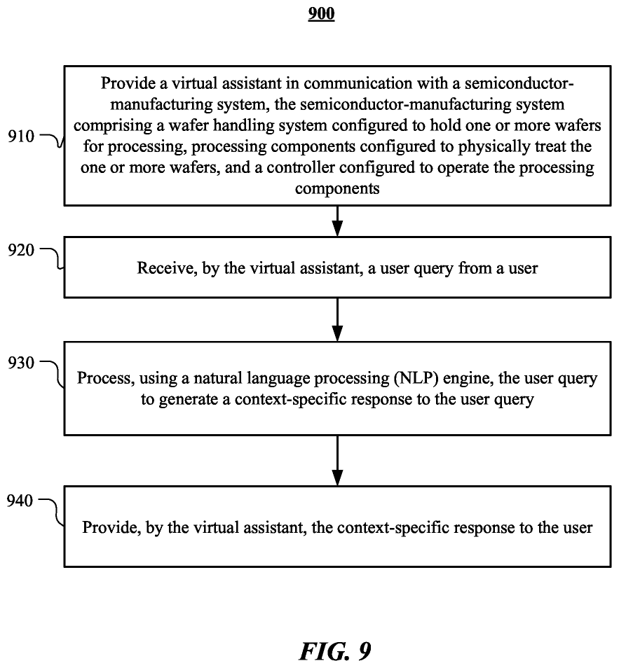

FIG. 9 illustrates an example method 900 for processing a user query and providing a context-specific response to the user query, in accordance with particular embodiments. The method 900 can begin at step 910, where a computing system (e.g., computing system 1000) can provide a virtual assistant (e.g., virtual assistant 150) in communication with a semiconductor-manufacturing system (e.g., semiconductor-manufacturing system 100). As shown and discussed in reference to FIG. 2, the semiconductor-manufacturing system can include a wafer handling system (e.g., wafer-handling system 120), one or more processing components (e.g., process components 110), and a controller (e.g., controller 130). The wafer handling system is configured to hold one or more wafers for processing. The processing components are configured to physically treat the one or more wafers. The controller is configured to operate the processing components. At step 920, the computing system can receive, by the virtual assistant, a user query from a user. The user query can relate to repair, maintenance, or usage of one or more semiconductor-manufacturing tools and the virtual assistant is configured to assist the user with respect to the one or more semiconductor-manufacturing tools. The user can be one of a field service engineer, a technician, or a process engineer associated with the semiconductor-manufacturing system.

At step 930, the computing system can process, using an NLP engine (e.g., NLP engine 160), the user query to generate a context-specific response to the user query. In particular embodiments, processing, using the NLP engine, the user query can include identifying one or more previous conversations between the user and the virtual assistant; identifying the intent of the user in the user query; extracting one or more entities in the user query; predicting a next action to be performed by the virtual assistant based on the one or more previous conversations, identified intent, and extracted entities; calling one or more action handlers to perform the next action; and generating the context-specific response to the user query based on results produced by the one or more action handlers. At step 940, the computing system can provide, by the virtual assistant, the context-specific response to the user.

Particular embodiments may repeat one or more steps of the method of FIG. 9, where appropriate. Although this disclosure describes and illustrates particular steps of the method of FIG. 9 as occurring in a particular order, this disclosure contemplates any suitable steps of the method of FIG. 9 occurring in any suitable order. Moreover, although this disclosure describes and illustrates an example method for processing a user query and providing a context-specific response to the user query, including the particular steps of the method of FIG. 9, this disclosure contemplates any suitable method for processing a user query and providing a context-specific response to the user query, including any suitable steps, which may include a subset of the steps of the method of FIG. 9, where appropriate. Furthermore, although this disclosure describes and illustrates particular components, devices, or systems carrying out particular steps of the method of FIG. 9, this disclosure contemplates any suitable combination of any suitable components, devices, or systems carrying out any suitable steps of the method of FIG. 9.

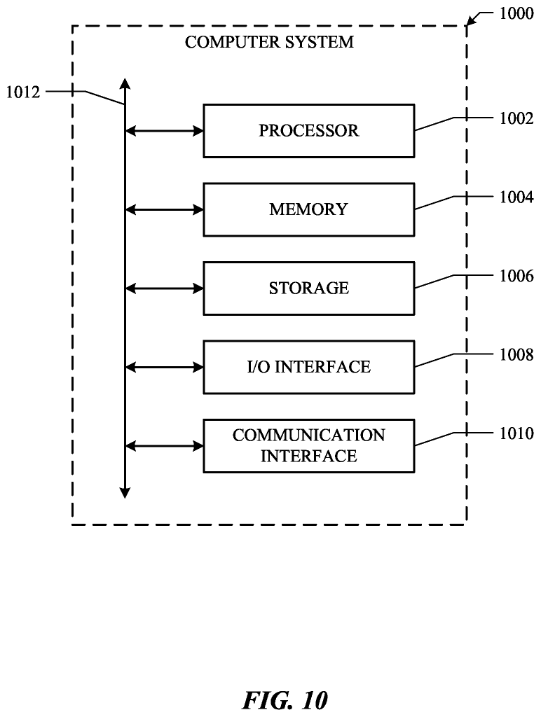

FIG. 10 illustrates an example computer system 1000. In particular embodiments, one or more computer systems 1000 perform one or more steps of one or more methods described or illustrated herein. In particular embodiments, one or more computer systems 1000 provide functionality described or illustrated herein. In particular embodiments, software running on one or more computer systems 1000 performs one or more steps of one or more methods described or illustrated herein or provides functionality described or illustrated herein. Particular embodiments include one or more portions of one or more computer systems 1000. Herein, reference to a computer system may encompass a computing device, and vice versa, where appropriate. Moreover, reference to a computer system may encompass one or more computer systems, where appropriate.

This disclosure contemplates any suitable number of computer systems 1000. This disclosure contemplates computer system 1000 taking any suitable physical form. As example and not by way of limitation, computer system 1000 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an AR/VR device, or a combination of two or more of these. Where appropriate, computer system 1000 may include one or more computer systems 1000; be unitary or distributed; span multiple locations; span multiple machines; span multiple data centers; or reside in a cloud, which may include one or more cloud components in one or more networks. Where appropriate, one or more computer systems 1000 may perform without substantial spatial or temporal limitation one or more steps of one or more methods described or illustrated herein. As an example and not by way of limitation, one or more computer systems 1000 may perform in real time or in batch mode one or more steps of one or more methods described or illustrated herein. One or more computer systems 1000 may perform at different times or at different locations one or more steps of one or more methods described or illustrated herein, where appropriate.

In particular embodiments, computer system 1000 includes a processor 1002, memory 1004, storage 1006, an input/output (I/O) interface 1008, a communication interface 1010, and a bus 1012. Although this disclosure describes and illustrates a particular computer system having a particular number of particular components in a particular arrangement, this disclosure contemplates any suitable computer system having any suitable number of any suitable components in any suitable arrangement.

In particular embodiments, processor 1002 includes hardware for executing instructions, such as those making up a computer program. As an example and not by way of limitation, to execute instructions, processor 1002 may retrieve (or fetch) the instructions from an internal register, an internal cache, memory 1004, or storage 1006; decode and execute them; and then write one or more results to an internal register, an internal cache, memory 1004, or storage 1006. In particular embodiments, processor 1002 may include one or more internal caches for data, instructions, or addresses. This disclosure contemplates processor 1002 including any suitable number of any suitable internal caches, where appropriate. As an example and not by way of limitation, processor 1002 may include one or more instruction caches, one or more data caches, and one or more translation lookaside buffers (TLBs). Instructions in the instruction caches may be copies of instructions in memory 1004 or storage 1006, and the instruction caches may speed up retrieval of those instructions by processor 1002. Data in the data caches may be copies of data in memory 1004 or storage 1006 for instructions executing at processor 1002 to operate on; the results of previous instructions executed at processor 1002 for access by subsequent instructions executing at processor 1002 or for writing to memory 1004 or storage 1006; or other suitable data. The data caches may speed up read or write operations by processor 1002. The TLBs may speed up virtual-address translation for processor 1002. In particular embodiments, processor 1002 may include one or more internal registers for data, instructions, or addresses. This disclosure contemplates processor 1002 including any suitable number of any suitable internal registers, where appropriate. Where appropriate, processor 1002 may include one or more arithmetic logic units (ALUs); be a multi-core processor; or include one or more processors 1002. Although this disclosure describes and illustrates a particular processor, this disclosure contemplates any suitable processor.

In particular embodiments, memory 1004 includes main memory for storing instructions for processor 1002 to execute or data for processor 1002 to operate on. As an example and not by way of limitation, computer system 1000 may load instructions from storage 1006 or another source (such as, for example, another computer system 1000) to memory 1004. Processor 1002 may then load the instructions from memory 1004 to an internal register or internal cache. To execute the instructions, processor 1002 may retrieve the instructions from the internal register or internal cache and decode them. During or after execution of the instructions, processor 1002 may write one or more results (which may be intermediate or final results) to the internal register or internal cache. Processor 1002 may then write one or more of those results to memory 1004. In particular embodiments, processor 1002 executes only instructions in one or more internal registers or internal caches or in memory 1004 (as opposed to storage 1006 or elsewhere) and operates only on data in one or more internal registers or internal caches or in memory 1004 (as opposed to storage 1006 or elsewhere). One or more memory buses (which may each include an address bus and a data bus) may couple processor 1002 to memory 1004. Bus 1012 may include one or more memory buses, as described below. In particular embodiments, one or more memory management units (MMUs) reside between processor 1002 and memory 1004 and facilitate accesses to memory 1004 requested by processor 1002. In particular embodiments, memory 1004 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 1004 may include one or more memories 1004, where appropriate. Although this disclosure describes and illustrates particular memory, this disclosure contemplates any suitable memory.

In particular embodiments, storage 1006 includes mass storage for data or instructions. As an example and not by way of limitation, storage 1006 may include a hard disk drive (HDD), a floppy disk drive, flash memory, an optical disc, a magneto-optical disc, magnetic tape, or a Universal Serial Bus (USB) drive or a combination of two or more of these. Storage 1006 may include removable or non-removable (or fixed) media, where appropriate. Storage 1006 may be internal or external to computer system 1000, where appropriate. In particular embodiments, storage 1006 is non-volatile, solid-state memory. In particular embodiments, storage 1006 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 1006 taking any suitable physical form. Storage 1006 may include one or more storage control units facilitating communication between processor 1002 and storage 1006, where appropriate. Where appropriate, storage 1006 may include one or more storages 1006. Although this disclosure describes and illustrates particular storage, this disclosure contemplates any suitable storage.

In particular embodiments, I/O interface 1008 includes hardware, software, or both, providing one or more interfaces for communication between computer system 1000 and one or more I/O devices. Computer system 1000 may include one or more of these I/O devices, where appropriate. One or more of these I/O devices may enable communication between a person and computer system 1000. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 1008 for them. Where appropriate, I/O interface 1008 may include one or more device or software drivers enabling processor 1002 to drive one or more of these I/O devices. I/O interface 1008 may include one or more I/O interfaces 1008, where appropriate. Although this disclosure describes and illustrates a particular I/O interface, this disclosure contemplates any suitable I/O interface.

In particular embodiments, communication interface 1010 includes hardware, software, or both providing one or more interfaces for communication (such as, for example, packet-based communication) between computer system 1000 and one or more other computer systems 1000 or one or more networks. As an example and not by way of limitation, communication interface 1010 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 1010 for it. As an example and not by way of limitation, computer system 1000 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 1000 may communicate with a wireless PAN (WPAN) (such as, for example, a BLUETOOTH WPAN), a WI-FIF1 network, a WI-MAX network, a cellular telephone network (such as, for example, a Global System for Mobile Communications (GSM) network), or other suitable wireless network or a combination of two or more of these. Computer system 1000 may include any suitable communication interface 1010 for any of these networks, where appropriate. Communication interface 1010 may include one or more communication interfaces 1010, where appropriate. Although this disclosure describes and illustrates a particular communication interface, this disclosure contemplates any suitable communication interface.

In particular embodiments, bus 1012 includes hardware, software, or both coupling components of computer system 1000 to each other. As an example and not by way of limitation, bus 1012 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture

(ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 1012 may include one or more buses 1012, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, the embodiments disclosed herein are only examples, and the scope of this disclosure is not limited to them. Particular embodiments may include all, some, or none of the components, elements, features, functions, operations, or steps of the embodiments disclosed herein. Furthermore, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend.

The subject matter that can be claimed includes not only the particular combinations of features set out in the attached claims, but also includes other combinations of features. Moreover, any of the embodiments or features described or illustrated herein can be claimed in a separate claim or in any combination with any embodiment or feature described or illustrated herein or with any features of the attached claims. Furthermore, although this disclosure describes or illustrates particular embodiments as providing particular advantages, particular embodiments may provide none, some, or all of these advantages.

Embodiments according to the invention are in particular disclosed in the attached claims directed to a method, a storage medium, a system and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim or in any combination with any embodiment or feature described or depicted herein or with any of the features of the attached claims.

Reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

1. A system comprising:
a wafer handling system configured to hold one or more wafers for processing;
processing components configured to physically treat the one or more wafers;
a controller configured to operate the processing components; and
a virtual assistant, in communication with a natural language processing (NLP) engine, configured to receive a user query from a user, understand an intent or context of the user query, and provide a context-specific response to the user query.

2. The system of claim 1, wherein the NLP engine comprises:
a co-referencing module configured to identify one or more previous conversations between the user and the virtual assistant;
an intent identifier configured to identify the intent of the user in the user query;
an entity extractor configured to extract one or more entities in the user query;
an action predictor configured to predict a next action to be performed by the virtual assistant based on the one or more previous conversations, identified intent, and extracted entities;
an action performer configured to call one or more action handlers to perform the next action; and
a response generator configured to generate the context-specific response to the user query based on results produced by the one or more action handlers.

3. The system of claim 1, wherein the NLP engine is a trained model that is trained based on a transformer model architecture and using relatively large volumes of semiconductor data.

4. The system of claim 1, wherein the NLP engine is used for one or more of:
named entity recognition;
text generation; or
question answering.

5. The system of claim 1, wherein the virtual assistant is configured to assist the user with respect to one or more semiconductor-manufacturing tools.

6. The system of claim 1, wherein the user query relates to repair, maintenance, or usage of one or more semiconductor-manufacturing tools.

7. The system of claim 1, further comprising:
a content search engine accessible to one or more of the virtual assistant or the NLP engine, the content search engine including processed data from one or more data sources, wherein the one or more of the virtual assistant or the NLP engine uses the processed data to provide the context-specific response to the user query.

8. The system of claim 7, wherein the processed data comprises data extracted from user manuals, Portable Document Format (PDF) files, PowerPoint (PPT) files, text-data files, or media files associated with one or more semiconductor-manufacturing tools.

9. The system of claim 1, further comprising:
an artificial intelligence (AI) engine configured to monitor operations of one or more semiconductor manufacturing tools and predict failure conditions.

10. The system of claim 9, wherein the AI engine is configured to generate a response to the user query received via the virtual assistant, the response being semantically matched to the user query.

11. The system of claim 1, further comprising:
user interface components to display the user query and the context-specific response by the virtual assistant.

12. The system of claim 1, wherein the user query is a natural language query.

13. The system of claim 1, wherein the user is one of a field service engineer, a technician, or a process engineer associated with a semiconductor-manufacturing system.

14. The system of claim 1, wherein the virtual assistant is one of a conversational bot, smart bot, a text chat bot, a speech-to-text chat bot, or a virtual consultant.

15. The system of claim 1, wherein the virtual assistant is an NLP-based bot.

16. A method comprising:
providing a virtual assistant in communication with a semiconductor-manufacturing system, the semiconductor-manufacturing system comprising a wafer handling system configured to hold one or more wafers for processing, processing components configured to physically treat the one or more wafers, and a controller configured to operate the processing components;
receiving, by the virtual assistant, a user query from a user;
processing, using a natural language processing (NLP) engine, the user query to generate a context-specific response to the user query; and
providing, by the virtual assistant, the context-specific response to the user.

17. The method of claim 16, wherein processing, using the NLP engine, the user query comprises:
identifying one or more previous conversations between the user and the virtual assistant;
identifying the intent of the user in the user query;
extracting one or more entities in the user query;
predicting a next action to be performed by the virtual assistant based on the one or more previous conversations, identified intent, and extracted entities;
calling one or more action handlers to perform the next action; and
generating the context-specific response to the user query based on results produced by the one or more action handlers.

18. The method of claim 16, wherein the virtual assistant is configured to assist the user with respect to one or more semiconductor-manufacturing tools.

19. The method of claim 16, wherein the user query relates to repair, maintenance, or usage of one or more semiconductor-manufacturing tools.

20. The method of claim 16, wherein the user is one of a field service engineer, a technician, or a process engineer associated with the semiconductor-manufacturing system.
